(19) United States
(12) Patent Application Publication
(10) Pub. No.: US 2009/0212444 A1
(43) Pub. Date: Aug. 27, 2009

(54) SEMICONDUCTOR PACKAGE AND METHOD OF MANUFACTURING THE SAME

(75) Inventor: Li-Cheng Shen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/235,616

(22) Filed: Sep. 23, 2008

(30) Foreign Application Priority Data
Feb. 21, 2008 (TW) 97106056

(51) Int. Cl. H01L 23/52; H01L 21/00

(52) U.S. Cl. 257/779; 438/118; 257/E23.141; 257/E21.001

(57) ABSTRACT

A semiconductor package including a substrate, a circuit pattern, a chip, at least one conductive material and an adhesive is provided. The substrate has a first surface, a second surface opposite thereto, and at least one through hole which penetrates the first surface and the second surface. The circuit pattern structure is disposed on the second surface and has at least one connecting pad disposed at the through hole. The chip is disposed on the first surface of the substrate. The chip has at least one conductive post, wherein the conductive post and the conductive material are disposed inside the through hole, and the conductive post is electrically connected with the pattern circuit structure through the conductive material. The adhesive is disposed between the chip and the substrate. A manufacturing method of the semiconductor structure is also provided.

### CROSS-REFERENCE TO RELATED APPLICATION

This application claims the priority benefit of Taiwan application serial no. 97106056, filed on Feb. 21, 2008. The entirety of the above-mentioned patent application is hereby incorporated by reference herein and made a part of this specification.

### BACKGROUND OF THE INVENTION

1. Field of the Invention

The present invention relates to an electronic device, and in particular, to a semiconductor package and a method of manufacturing the same.

2. Description of Related Art

FIG. 1A is a cross-sectional view of a conventional semiconductor package. Referring to FIG. 1A, the conventional semiconductor package 100 includes a substrate 110, a chip 120, a plurality of solder balls 130 and under-fill 140. The substrate 110 has a plurality of bump pads 112 and a plurality of solder ball pads 114. The solder ball 130 is disposed on the solder ball pad 114. The chip 120 is disposed on the substrate 110. The chip 120 has a plurality of bumps 122, and the bumps 122 are electrically connected with the bump pads 112 on the substrate 110. The under-fill 140 is filled between the substrate 110 and the chip 120.

The chip 120 is fixed to the substrate 110 through the under-fill 140 therebetween to reduce the thermal stress due to the coefficient of thermal expansion (CTE) mismatch of the chip 120 and the substrate 110. However, the chip 120 is electrically connected with the substrate 110 through the bumps 112, so that a signal transmission path from the chip 120 to the solder balls 130 can not be further shortened, which is unfavorable to the high frequency application.

FIG. 1B is a cross-sectional view of a conventional semiconductor package. Referring to FIG. 1B, the semiconductor package 200 includes a substrate 210, a chip 220, and a plurality of conductive materials 230. The substrate 210 has a patterned trace 212 and a plurality of blind vias 214. The chip 220 is disposed over the substrate 210 such that a gap is maintained between the chip 220 and the substrate 210 via the conductive posts 222. The chip 220 has a plurality of conductive posts 222 disposed in the blind vias 214. The conductive materials 230 is disposed in the blind vias 214 to fix the conductive post so as to fix the chip 220 on the substrate 210.

Compared with the semiconductor package 100, the semiconductor package 200 can shorten the signal transmission path, but the chip 220 is fixed to the substrate 210 merely through the bonding of the conductive post 222 and the conductive material 230. Therefore, the electrical connection between the chip 120 and the substrate 110 is easily to be damaged by external forces and the reliability of the semiconductor package 200 is deteriorated.

### SUMMARY OF THE INVENTION

The present invention provides a method for manufacturing the above-mentioned semiconductor package.

The present invention provides a semiconductor package including a substrate, a circuit pattern structure, a chip, at least one conductive material, and an adhesive. The substrate having a first surface, a second surface opposite thereto, and a through hole penetrating the first surface and the second surface. The circuit pattern structure is disposed on the second surface and has at least one connecting pad disposed corresponding to the through hole. The chip is disposed on the first surface of the substrate and has at least one conductive post, wherein the conductive post is disposed inside the through hole. The conductive material is disposed inside the through hole, and the conductive post is electrically connected with the circuit pattern structure through the conductive material and the connecting pad. The adhesive is disposed between the chip and the substrate.

The present invention further provides a method of manufacturing a semiconductor package. The method of manufacturing the semiconductor package includes steps as follows: First, a substrate is provided, wherein the substrate has a first surface, a second surface opposite thereto, and at least one through hole. The first surface is opposite to second surface, and the through hole penetrates the first surface and the second surface. A circuit pattern structure is disposed on the substrate and has at least one connecting pad disposed at the through hole. Then, a chip is fastened on the first surface of the substrate by an adhesive, wherein the chip has at least one conductive post, and the conductive post is disposed inside the through hole. After that, the adhesive is cured by heating process, for example. Afterwards, at least one conductive material is filled into the through hole to make the through hole filled up with the conductive material, and the conductive post is electrically connected with the circuit pattern structure through the conductive material and the connecting pad.

Based on the above, in the semiconductor package, the chip and the substrate are electrically connected to each other through the conductive post and the conductive material embedded in the through hole, and the chip is fastened on the substrate by the adhesive.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the present invention, and are incorporated in and constitute a part of this specification. The drawings illustrate embodiments of the invention and, together with the description, serve to explain the principles of the invention. FIGS. 1A and 1B are cross-sectional views of a conventional semiconductor package.

FIGS. 2A to 2D illustrate steps of manufacturing a semiconductor package according to one embodiment of the present invention.

FIGS. 3A and 3B are schematic views illustrating disposing a chip on a substrate according to another embodiment of the present invention.

FIGS. 4 to 10 are cross-sectional views illustrating the semiconductor package according to other embodiments of the present invention.

### DESCRIPTION OF EMBODIMENTS

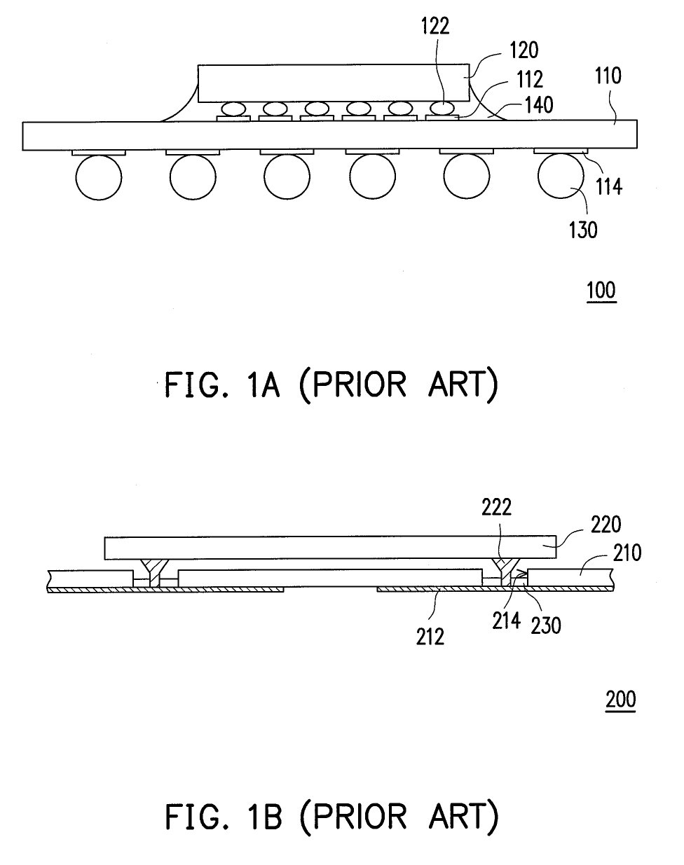

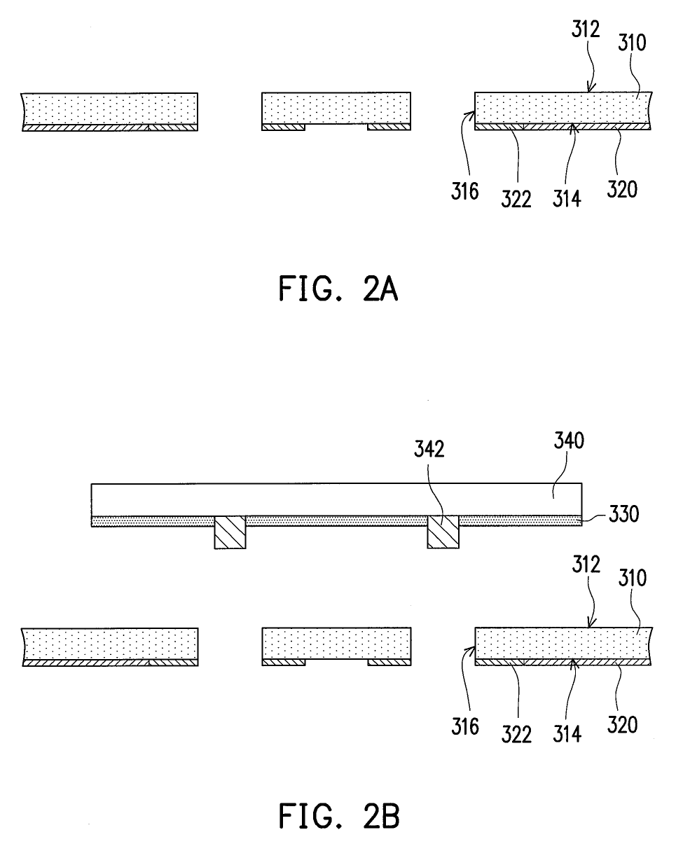

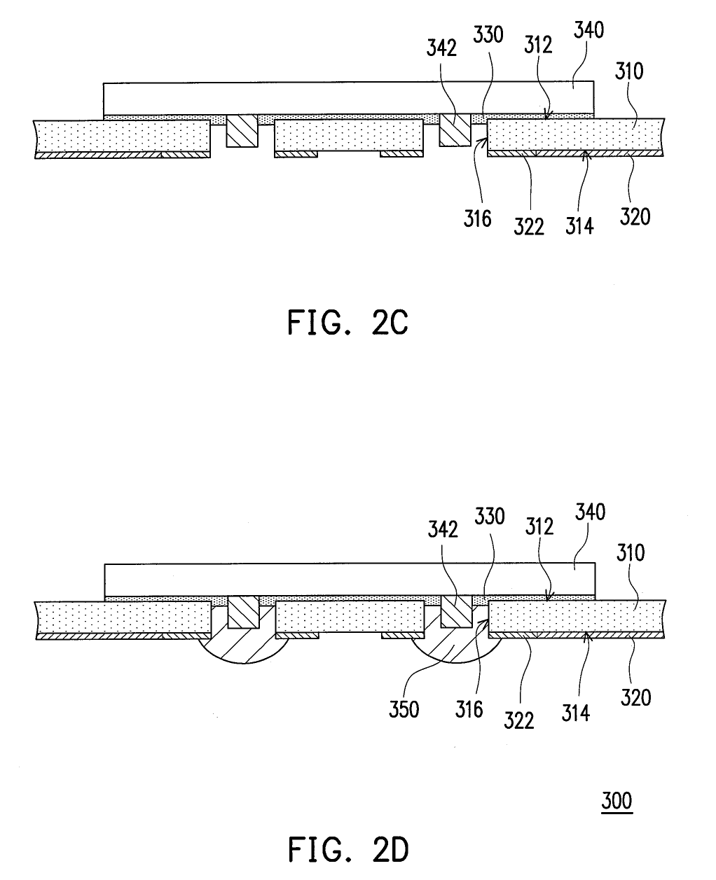

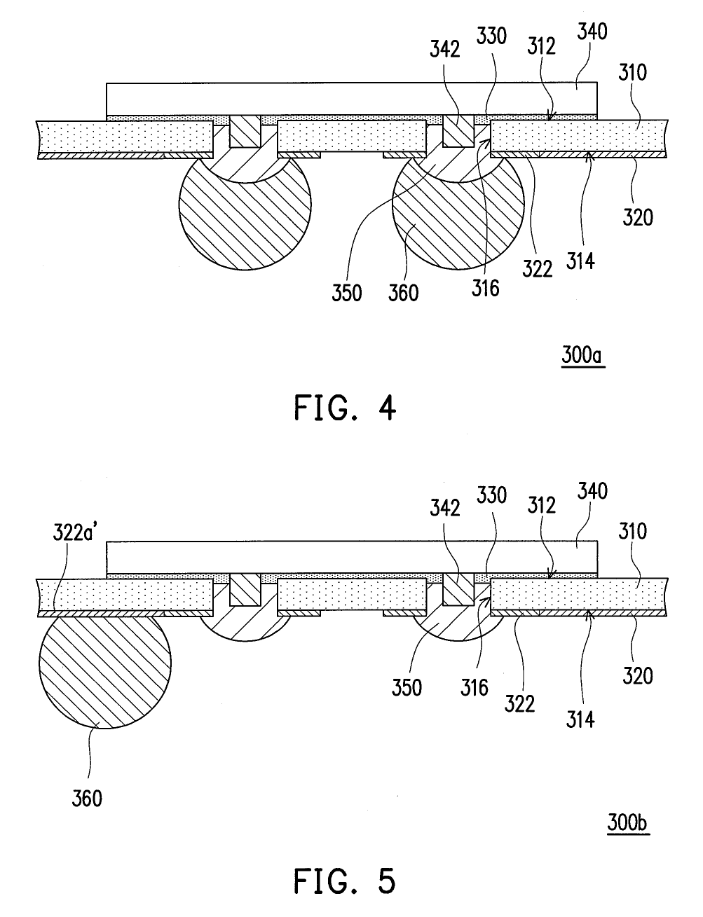

FIGS. 2A to 2D are steps of manufacturing a semiconductor package according to one embodiment of the present invention. Referring to FIGS. 2A to 2D, a method of manufacturing a semiconductor package 300 includes steps as follows. First, referring to FIG. 2A, a substrate 310 is provided. The substrate 310 has a first surface 312, a second surface 314 opposite thereto, and a plurality of through holes 316. The through hole 316 penetrates the first surface 312 and the second surface 314. A circuit pattern structure 320 is disposed on the substrate 310, wherein the circuit pattern structure 320 has a plurality of connecting pads 322, and the connecting pads 322 are disposed corresponding to the through holes 316. According to the present embodiment, the relative position of the connecting pad 322 and the through hole can be various. For example, the connecting pad 322 can surround the through hole 316, or can simply be distributed around the through hole 316. According to the present invention, the relative position of the connecting pad 322 and the through hole 316 is decided on the premise that the connecting pad and the through hole can be electrically connected to each other through the conductive material 350 (shown in FIG. 4) filled in the trough hole 316. In the present invention, the relative position of the connecting pad 322 and the through hole 316 is not limited to that shown in FIG. 2A.

Then, referring to FIGS. 2B and 2C, a chip 340 is fastened on the first surface 312 of the substrate 310 by an adhesive 330. The chip 340 has a plurality of conductive posts 342 disposed inside the through holes 316. In detail, in the present embodiment, the adhesive 330 can be stuck on the chip 340 first, as shown in FIG. 2B. After that, as shown in FIG. 2C, the chip 340 is disposed on the substrate 310 in order to make the chip 340 supported by the substrate 310, and to make the conductive posts 342 disposed in the through holes 316. Afterwards, the adhesive 330 is cured by heating process, for example. Additionally, the adhesive 330 is a thermosetting resin or a UV curing resin, for example.

A person of ordinary skill in the art can also use other methods to fasten the chip 340 on the substrate 310 by the adhesive 330, which will be described later.

Thereafter, as shown in FIG. 2D, a plurality of conductive materials 350 is filled into the through holes 316 to make the through holes 316 filled up with the conductive materials 350, and the conductive post 342 is electrically connected with the circuit pattern structure 320 through the conductive materials 350 and the connecting pads 322. So far, the manufacture of the semiconductor package 300 is substantially completed.

According to the above-mentioned embodiment, the chip 340 is electrically connected with the substrate 310 through the conductive posts 342 and the conductive materials 350 embedded in the through holes 316, so that the signal transmission path is shortened, and the thickness of the semiconductor structure 300 is significantly decreased. In addition, the chip 340 is disposed on the substrate 310, and the chip 340 is fastened on the substrate 310 by the adhesive 330. Thereby, the structure strength of the semiconductor package 300 is increased, and so that the reliability of the semiconductor package 300 is increased.

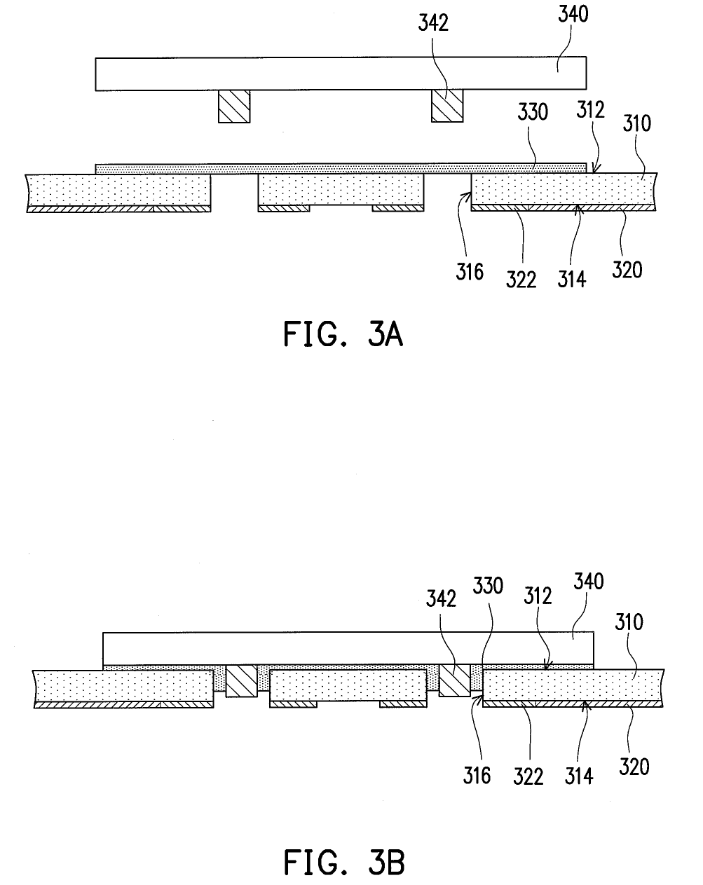

The steps of fastening the chip 340 on the substrate 310 by the adhesive 330 are not limited to the above-mentioned, and can be implemented through other methods by persons skilled in the art. FIGS. 3A and 3B are schematic views illustrating disposing the chip on the substrate according to another embodiment of the present invention. Please refer to FIGS. 3A and 3B. According to the present embodiment, the adhesive 330 can be disposed on the chip 310 first, as shown in FIG. 3A. After that, as shown in FIG. 3B, the chip 340 is disposed on the substrate 310 in order to make the chip 340 supported by the substrate 310, and to make the conductive posts 342 penetrate the adhesive 330 into the through holes 316. Afterwards, the adhesive 330 is cured by heating process, for example.

Moreover, although the present embodiment has more than one connecting pad 332, through hole 316, conductive post 342, and conductive material 350, but the present invention is not limited thereto. The numbers of the connecting pads 322, the through holes 316, the conductive posts 342, and the conductive materials 350 disposed by persons skilled in the art can be variable according to the actual demands. For example, a connecting pad 322, a through hole 316, a conductive post 342, and a conductive material 350 are disposed.

FIGS. 4 to 10 are cross-sectional views illustrating the semiconductor package according to other embodiments of the present invention. Please refer to FIGS. 4 to 10. In the semiconductor package 300a according to the embodiment of FIG. 4, a solder ball 360 is formed on the second surface 314 of the substrate 310 after the implementation of filling the conductive material 350 into the through hole 316. The solder ball 360 can be disposed on the connecting pad 322 and is electrically connected with the conductive post 342 through the conductive material 350. The solder ball 360 can also be disposed in other positions of the circuit pattern structure 320. Referring to FIG. 5, in the present embodiment, the solder ball 360 of the semiconductor package 300b can be disposed on one solder ball pad 322a′ of the circuit pattern structure 320, and is electrically connected with the conductive post 342 through the circuit pattern structure 320.

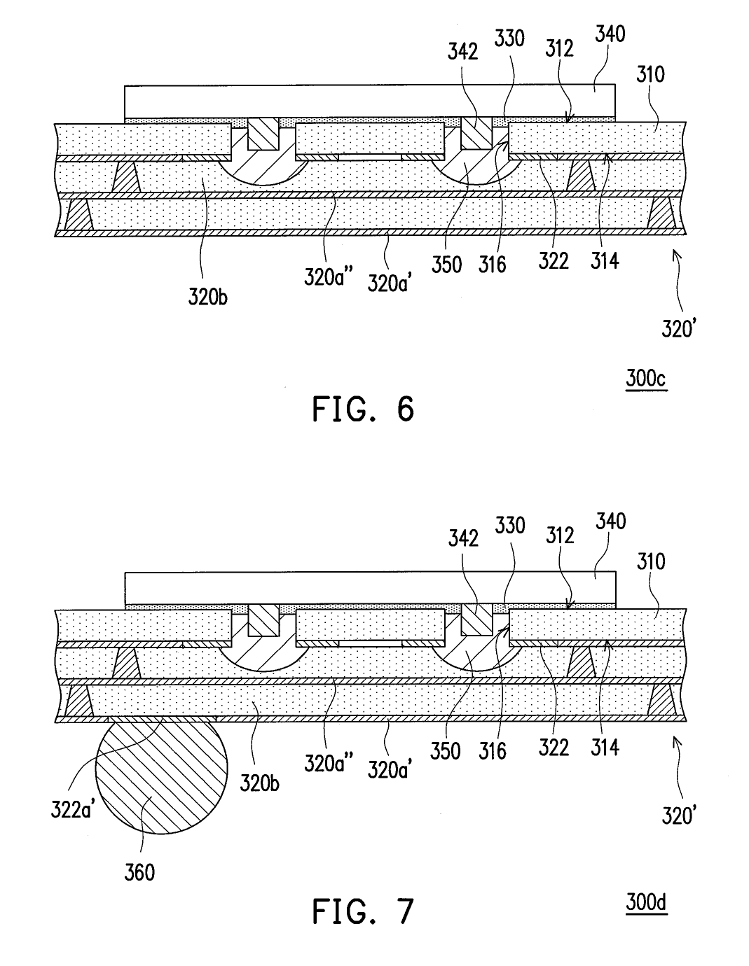

In addition to the single-layer circuit pattern structure 320, the circuit pattern structure of the present invention can be multilayer. Referring to FIG. 6, in the present embodiment, the circuit pattern structure 320′ of the semiconductor package 300c includes at least one circuit pattern layer 320a and at least one dielectric layer 320b, wherein the circuit pattern layer 320a has the connecting pad 322, and the circuit pattern layer 320a and the dielectric layer 320b are laminated alternately. More specifically, the circuit pattern layer 320a can include a surface circuit layer 320a′ and a plurality of inter-layered circuit layers 320a″, wherein the inter-layered circuit layer 320a″ disposed on the substrate 310 has the connecting pad 322, and each layer of the circuit pattern layer 320a can be electrically connected to one another through the through hole 322b of the dielectric layer 320b.

In addition, the present embodiment can also include the solder ball 360. Referring to FIG. 7, in the present embodiment, the surface circuit layer 320a′ of the semiconductor package 300d can include a plurality of solder ball pads 322a′. The solder ball 360 can be formed on the surface circuit layer 320a′ and is electrically connected with the conductive post 342 through the inter-layered circuit layer 320a″ and the conductive material 350. Furthermore, the numbers of the solder balls 360, the circuit pattern layers 320a, the dielectric layers 320b, the inter-layered circuit layer 320a″, and the solder ball pads 322a′ are not limited in the present invention, and can be modified by persons skilled in the art as required according to the disclosure in the above-mentioned embodiment.

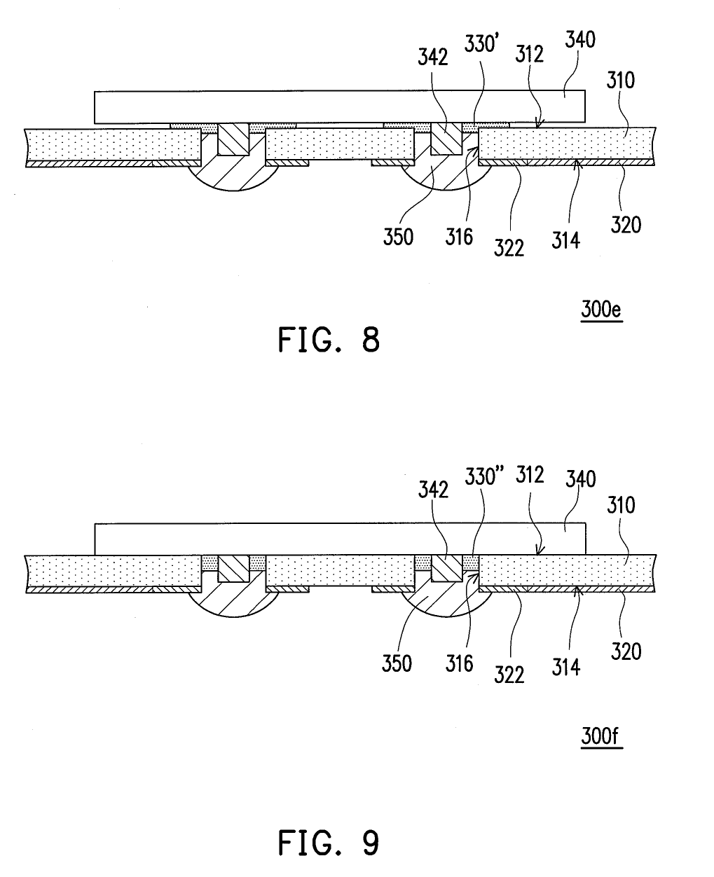

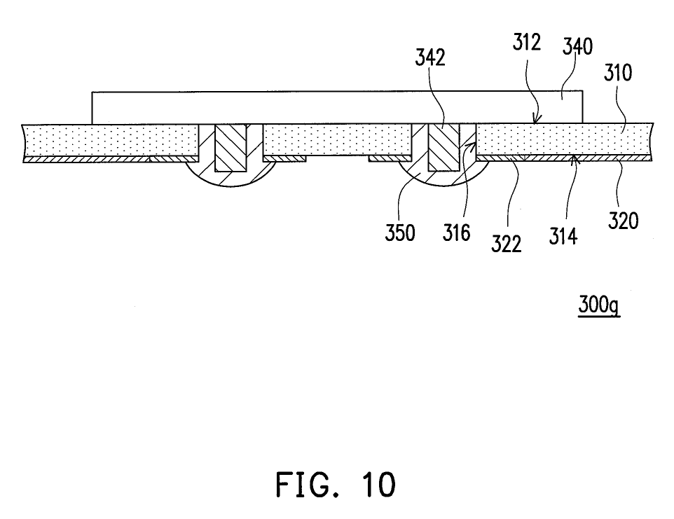

Moreover, the adhesive can be arranged in a way different from the above-mentioned. Referring to FIG. 8, in the present embodiment, the area of an adhesive 330′ of a semiconductor package 300e is smaller than that of the chip 340. For example, the area of the adhesive 330′ of the semiconductor package 300e can be smaller than that of the connecting pad 322. Referring to FIG. 9, in the present embodiment, an adhesive 330″ of a semiconductor package 300f is not disposed between the chip 340 and the substrate 310, and instead is disposed in the through hole 316. Referring to FIG. 10, in the present embodiment, the semiconductor package 300f has no adhesive, the conductive material 350 is in contact with the chip 340 to fix the chip 340, and the height of the conductive post 342 is larger than the thickness of the substrate 310. It should be noted that, the semiconductor package according to the embodiments of FIGS. 8 to 10 can include the solder ball and the multilayer structure just as the embodiments of FIGS. 4 to 7. Persons skilled in the field can make the arrangement according to the disclosure mentioned above, so detailed descriptions are omitted. In addition, in the embodiments of FIGS. 2D to 9, the height of the conductive post is smaller than the thickness of the substrate; however, the present invention is not limited thereto, and persons skilled in the art can make the height of the conductive post of each of the semiconductor packages of FIGS. 2D to 9 higher than the thickness of the substrate based on the disclosure mentioned above.

In summary, according to the above-mentioned embodiments, the chip is electrically connected with the substrate through the conductive post and the conductive material embedded in the through hole, so that the signal transmission path is shortened, and the thickness of the semiconductor structure 300 is effectively decreased. In addition, the chip is disposed on the substrate, and the chip is fastened on the substrate by the adhesive. Thereby, the semiconductor package is firm, so that the structure strength of the semiconductor package is increased, and the reliability thereof is also increased.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A semiconductor package, comprising:
a substrate having a first surface, a second surface opposite thereto, and a through hole penetrating the first surface and the second surface;
a circuit pattern structure disposed on the second surface and having at least one connecting pad disposed corresponding to the through hole;
a chip disposed on the first surface of the substrate and having at least one conductive post, wherein the conductive post is disposed inside the through hole;
at least one conductive material disposed inside the through hole, the conductive post being electrically connected with the pattern circuit structure through the conductive material; and
an adhesive disposed between the chip and the substrate.

2. The semiconductor package according to claim 1, wherein an area of the adhesive is smaller than that of the chip, and the adhesive surrounds the conductive post.

3. The semiconductor package according to claim 1, wherein the adhesive comprises a thermosetting resin or a UV curing resin.

4. The semiconductor package according to claim 1, wherein the conductive material comprises solder paste, conductive polymer, or conductive particles.

5. The semiconductor package according to claim 1, wherein a material of the conductive post comprises tin, copper or gold.

6. The semiconductor package according to claim 1, wherein the circuit pattern structure comprises a single-layer circuit pattern structure.

7. The semiconductor package according to claim 6, further comprising at least one solder ball disposed on the second surface, the solder ball being electrically connected with the conductive post through the circuit pattern structure.

8. The semiconductor package according to claim 6, further comprising at least one solder ball disposed on the second surface, the solder ball being electrically connected with the conductive post through the circuit pattern structure and the conductive material.

9. The semiconductor package according to claim 1, wherein the circuit pattern structure comprises a multilayer circuit pattern structure.

10. The semiconductor package according to claim 9, wherein the multilayer circuit pattern structure comprises:
at least one circuit pattern layer having the connecting pad; and
at least one dielectric layer, wherein the circuit pattern layer and the dielectric layer are alternately laminated.

11. The semiconductor package according to claim 10, wherein the circuit pattern layer comprises at least one surface circuit layer and at least one inter-layered circuit layer, and the inter-layered circuit layer comprises the connecting pad.

12. The semiconductor package according to claim 11, further comprising at least one solder ball, wherein the surface circuit layer comprises at least one solder ball pad, the solder ball is disposed at the solder ball pad, and the solder ball is electrically connected with the conductive post through the circuit pattern structure and the conductive material.

13. A method of manufacturing a semiconductor package, comprising:
providing a substrate, the substrate having a first surface, a second surface opposite thereto, and a through hole penetrating the first surface and the second surface, wherein a circuit pattern structure is disposed on the substrate, and the circuit pattern structure has at least one connecting pad disposed at the through hole;
fastening a chip on the first surface of the substrate by an adhesive, wherein the chip has at least one conductive post, and the conductive post is disposed inside the through hole;
curing the adhesive; and
filling at least one conductive material into the through hole, wherein the conductive post is electrically connected with the pattern circuit structure through the conductive material and the connecting pad.

14. The method of manufacturing the semiconductor package according to claim 13, further comprising forming at least one solder ball on the connecting pad after the conductive material is filled into the through hole.

15. The method of manufacturing the semiconductor package according to claim 13, further comprising forming at least one solder ball on the second surface after the conductive material is filled into the through hole, and electrically connecting the solder ball to the conductive post through the circuit pattern structure.

16. The method of manufacturing the semiconductor package according to claim 13, wherein the circuit pattern structure comprises:
at least one circuit pattern layer having the connecting pad; and
at least one dielectric layer, wherein the circuit pattern layer and the dielectric layer are alternately laminated.

17. The method of manufacturing the semiconductor package according to claim 16, wherein the circuit pattern layer comprises at least one surface circuit layer and at least one inter-layered circuit layer, and the inter-layered circuit layer comprises the connecting pad.

18. The method of manufacturing the semiconductor package according to claim 17, wherein the surface circuit layer has at least one solder ball pad, the method of manufacturing the semiconductor package further comprises forming at least one solder ball on the solder ball pad, and the solder ball is electrically connected with the conductive post through the conductive material.

19. A semiconductor package, comprising:
a substrate having a first surface, a second surface opposite thereto, and a through hole penetrating the first surface and the second surface;
a circuit pattern structure disposed on the second surface and having at least one connecting pad disposed corresponding to the through hole;
a chip disposed on the first surface of the substrate and having at least one conductive post, wherein the conductive post is disposed inside the through hole, and a height of the conductive post is larger than a thickness of the substrate; and
at least one conductive material disposed inside the through hole, wherein the conductive post is electrically connected with the pattern circuit structure through the conductive material and the connecting pad, and the conductive material is in contact with the chip.

20. The semiconductor package according to claim 19, wherein the conductive material comprises solder paste, conductive polymer, or conductive particles.

21. The semiconductor package according to claim 19, wherein a material of the conductive post comprises tin, copper or gold.

22. The semiconductor package according to claim 19, wherein the circuit pattern structure comprises a single-layer circuit pattern structure.

23. The semiconductor package according to claim 22, further comprising at least one solder ball disposed on the second surface, the solder ball being electrically connected with the conductive post through the circuit pattern structure.

24. The semiconductor package according to claim 22, further comprising at least one solder ball disposed on the second surface, the solder ball being electrically connected with the conductive post through the circuit pattern structure and the conductive material.

25. The semiconductor package according to claim 19, wherein the circuit pattern structure comprises a multilayer circuit pattern structure.

26. The semiconductor package according to claim 25, wherein the multilayer circuit pattern structure comprises:
at least one circuit pattern layer having the connecting pad; and
at least one dielectric layer, wherein the circuit pattern layer and the dielectric layer are alternately laminated.

27. The semiconductor package according to claim 26, wherein the circuit pattern layer comprises at least one surface circuit layer and at least one inter-layered circuit layer, and the inter-layered circuit layer comprises the connecting pad.

28. The semiconductor package according to claim 27, further comprising at least one solder ball, wherein the surface circuit layer comprises at least one solder ball pad, the solder ball is disposed at the solder ball pad, and the solder ball is electrically connected with the conductive post through the circuit pattern structure and the conductive material.

29. A semiconductor package, comprising:
a substrate having a first surface, a second surface opposite thereto, and a through hole penetrating the first surface and the second surface;
a circuit pattern structure disposed on the second surface and having at least one connecting pad disposed corresponding to the through hole;
a chip disposed on the first surface of the substrate and having at least one conductive post, wherein the conductive post is disposed inside the through hole;
at least one conductive material disposed inside the through hole, wherein the conductive post is electrically connected with the pattern circuit structure through the conductive material and the connecting pad; and
an adhesive disposed inside the through hole.

30. The semiconductor package according to claim 29, wherein the adhesive comprises a thermosetting resin or a UV curing resin.

31. The semiconductor package according to claim 29, wherein the conductive material comprises solder paste, conductive polymer, or conductive particles.

32. The semiconductor package according to claim 29, wherein a material of the conductive post comprises tin, copper or gold.

33. The semiconductor package according to claim 29, wherein the circuit pattern structure comprises a single-layer circuit pattern structure.

34. The semiconductor package according to claim 33, further comprising at least one solder ball disposed on the second surface, the solder ball being electrically connected with the conductive post through the circuit pattern structure.

35. The semiconductor package according to claim 33, further comprising at least one solder ball disposed on the second surface, the solder ball being electrically connected with the conductive post through the circuit pattern structure and the conductive material.

36. The semiconductor package according to claim 29, wherein the circuit pattern structure comprises a multilayer circuit pattern structure.

37. The semiconductor package according to claim 36, wherein the multilayer circuit pattern structure comprises:
at least one circuit pattern layer having the connecting pad; and
at least one dielectric layer, wherein the circuit pattern layer and the dielectric layer are alternately laminated.

38. The semiconductor package according to claim 37, wherein the circuit pattern layer comprises at least one surface circuit layer and at least one inter-layered circuit layer, and the inter-layered circuit layer comprises the connecting pad.

39. The semiconductor package according to claim 29, further comprising at least one solder ball, wherein the surface circuit layer comprises at least one solder ball pad, the solder ball is disposed at the solder ball pad, and the solder ball is electrically connected with the conductive post through the circuit pattern structure and the conductive material.
